(19) United States
(12) Patent Application Publication
(10) Pub. No.: US 2011/0228501 A1
(43) Pub. Date: Sep. 22, 2011

(54) ELECTRONIC DEVICE, AND METHOD OF MANUFACTURING ELECTRONIC DEVICE

(75) Inventor: Seiichi CHIBA, Minowa-machi (JP)

(73) Assignee: SEIKO EPSON CORPORATION, Tokyo (JP)

(21) Appl. No.: 13/044,829

(22) Filed: Mar. 10, 2011

(30) Foreign Application Priority Data
Mar. 19, 2010 (JP) 2010-063876

(51) Int. Cl. H05K 1/18; H01L 21/58

(52) U.S. Cl. 361/767; 29/25.01

(57) ABSTRACT

An electronic device having a base substrate on which a resonator element and a semiconductor device are mounted by being disposed in a horizontal direction, includes on one primary face of the base substrate: a resonator element mounting pad that is used for mounting the resonator element; a first semiconductor device connecting pad that is electrically connected to the resonator element mounting pad; a relay pad that is electrically connected to a monitoring electrode terminal formed on the other primary face of the base substrate; and a cutting pattern that electrically connects the first semiconductor device connecting pad and the relay pad, wherein the cutting pattern is cut off in a state in which the semiconductor device is mounted, and a concave dent portion is included on the surface of the base substrate that is a cutting-off position of the cutting pattern.

### BACKGROUND

1. Technical Field

The present invention relates to an electronic device including a base substrate that has one face on which a resonator element and a semiconductor device can be mounted by being aligned in the horizontal direction and a method of manufacturing the electronic device, and more particularly, to an electronic device of a type in which vibration characteristics can be detected from the other face of the base substrate after mounting of the resonator element, and a method of manufacturing the electronic device.

2. Related Art

Electronic devices that are represented by a crystal oscillator, an SAW filter, or the like include a resonator in which excitation is performed and a semiconductor integrated circuit (semiconductor device) having an oscillation circuit used for oscillating the resonator as its major configurations.

As electronic devices having such a configuration, various types having different dispositional forms of constituent elements according to the purpose of decreasing the mounting area or reducing the height are being developed. For example, in electronic devices of which the main purpose is to decrease the mounting area, a form in which a piezoelectric device and a semiconductor device are disposed in the vertical direction is frequently employed. On the other hand, in electronic devices of which the main purpose is to reduce the height, a form in which a piezoelectric device and a semiconductor device are horizontally disposed is frequently employed. In such electronic devices, even in a case where any of the dispositional forms is employed, after a resonator is configured by mounting and sealing a resonator element, the electrical characteristics of the resonator, such as the resonant frequency and the CI value are tested, and the electrical characteristics are adjusted as necessary. In order to satisfy such a demand, in electronic devices, a monitoring electrode terminal that is used for detecting the vibration characteristics that are unique to the resonator is disposed. Such a monitoring electrode terminal is generally disposed on a side face of the package configuring the electronic device. However, disposition of the terminal on the side face of the package becomes a factor that hinders miniaturization or height reduction of the electronic device, and thus development of various technologies is continuing.

For example, a technology disclosed in JP-A-2005-223640, as shown in FIG. 9, relates to an electronic device that employs a package base having a so-called H-type structure by configuring a resonator and a semiconductor device to be disposed in the vertical direction. In this electronic device 1, a pattern (not shown in the figure) that electrically connects a resonator element mounting pad 4 and an external terminal 7 used for mounting the electronic device 1 is formed on the rear face side of an intermediate substrate 2 on which a resonator element 3 is mounted, that is, a face on which a semiconductor device 5 is mounted. In addition, it is configured so that the testing of the vibration characteristics as a resonator can be performed through the external terminal 7. After the testing and the adjustment of the vibration characteristics are performed, the pattern electrically connecting the external terminal 7 and the resonator element mounting pad 4 is cut off, and the external terminal 7 can be configured to be independent as a terminal having a unique function.

In addition, a technology disclosed in JP-A-2009-27465, as shown in FIGS. 10A and 10B, employs a configuration in which a resonator and a semiconductor device are disposed in the horizontal direction. FIG. 10A is a diagram showing the cross-sectional configuration of an electronic device, and FIG. 10B is a diagram showing the planar configuration of the electronic device. In the electronic device 1a disclosed in JP-A-2009-27465, a monitoring electrode terminal 8a electrically connected to a resonator element mounting pad 4a is formed in a mounting space of a semiconductor device 5a disposed alongside a mounting space of a resonator element 3a. The monitoring electrode terminal 8a in such a dispositional form is coated with a resin 9a so as not to be externally exposed after the semiconductor device 5a is mounted.

In addition, a technology disclosed in JP-A-2008-301196 employs a form as shown in FIGS. 11A and 11B. FIG. 11A is a diagram showing the planar form of an electronic device, and FIG. 11B is a diagram showing the rear face form of the electronic device. In the electronic device 1b having such a form, an intermediate diameter pad 6b is formed in a semiconductor device mounting space. The intermediate diameter pad 6b is connected to a semiconductor device mounting pad 5b that is electrically connected to a resonator element mounting pad 4b through a cutting pattern 6b 1. In addition, on the rear face of a base substrate 2b on which the intermediate diameter pad 6b is disposed, a monitoring electrode terminal 8b is formed, in addition to an external terminal 7b. In the electronic device 1b having a package of such a form, after a resonator is configured, the vibration characteristics of the resonator are tested and adjusted through the monitoring electrode terminal 8b, and thereafter, a cutting pattern 6b1 is cut off so as to electrically cut off the monitoring electrode terminal 8b, thereby configuring the electronic device 1b.

In the technologies described above, structures appropriate for each of the purposes of miniaturization and reducing the height are formed while focusing on the disposition location or the use form of the monitoring electrode terminal. However, the technology disclosed in JP-A-2005-223640 relates to a structure that is not appropriate for reducing the height, which is regarded as an object of the invention. In addition, according to the technology disclosed in JP-A-2009-27465, the monitoring electrode terminal is disposed on the primary face on the side on which the resonator and the semiconductor device are mounted. Thus, when the vibration characteristics are adjusted, the probe is not brought into contact with the monitoring electrode terminal from the rear face side of the base substrate. Accordingly, in order to adjust the vibration characteristics, a dedicated holder having a terminal is necessary.

In the technology disclosed in JP-A-2008-301196, a configuration in which a probe can be brought into contact with a monitoring electrode terminal from the rear face side (the other primary face side) of the base substrate is employed. However, in a case where cutting of a cutting pattern that is cut off after testing and adjusting of the vibration characteristics is incomplete, there is a problem in that the vibration characteristics may deteriorate due to generation of stray capacitance or a short circuit may be formed at the time of mounting.

### SUMMARY

An advantage of some aspects of the invention is that provides an electronic device capable of providing a reliable cut state of a cutting pattern in a case where the cutting pattern is included in a base substrate and a method of manufacturing the electronic device.

The invention can be implemented in the following forms or application examples.

### APPLICATION EXAMPLE 1

This application example of the invention is directed to an electronic device having a base substrate on which a resonator element and a semiconductor device are mounted by being disposed in a horizontal direction. The electronic device includes on one primary face of the base substrate: a resonator element mounting pad that is used for mounting the resonator element; a first semiconductor device connecting pad that is electrically connected to the resonator element mounting pad; a relay pad that is electrically connected to a monitoring electrode terminal formed on the other primary face of the base substrate; and a cutting pattern that electrically connects the first semiconductor device connecting pad and the relay pad. The cutting pattern is cut off in a state in which the semiconductor device is mounted, and a concave dent portion is included on the surface of the base substrate that is a cutting-off position of the cutting pattern.

According to the above-described electronic device, the cut-off state of the cutting pattern can be reliably formed.

### APPLICATION EXAMPLE 2

This application example is directed to the electronic device according to the application example 1, wherein the relay pad is a second semiconductor device connecting pad that is used for mounting the semiconductor device, and the monitoring electrode terminal is a mounting terminal that is formed on the other face of the base substrate.

Since the mounting terminal (external mounting terminal) is used as a so-called monitoring electrode terminal, a probe contact face can be reliably secured even in a case where the package is miniaturized.

### APPLICATION EXAMPLE 3

This application example is directed to a method of manufacturing an electronic device that has a base substrate having one face on which a resonator element mounting pad that is used for mounting a resonator element, a first semiconductor device connecting pad that is electrically connected to the resonator element mounting pad, a relay pad that is electrically connected to a monitoring electrode terminal formed on the other face, and a cutting pattern that electrically connects the first semiconductor device connecting pad and the relay pad and is capable of mounting the resonator element and the semiconductor device by being disposed in a horizontal direction. The method includes: mounting the resonator element on the resonator element mounting pad; performing oscillation of the resonator element and adjustment of a resonant frequency through the monitoring electrode terminal; and forming a concave dent portion on the surface of the base substrate by cutting off the cutting pattern after the performing of oscillation and adjustment.

When an electronic device is manufactured by using the above-described method of manufacturing an electronic device, the cut-off state of the cutting pattern can be reliably formed.

### BRIEF DESCRIPTION OF THE DRAWINGS

The invention will be described with reference to the accompanying drawings, wherein like numbers reference like elements.

FIGS. 1A to 1C are diagrams showing the configuration of an electronic device according to an embodiment of the invention.

FIG. 2 is an exploded perspective view showing the configurations of the second substrate and third substrate.

FIG. 3 is a flowchart representing the process of manufacturing an electronic device.

FIG. 4 is a diagram showing the appearance of the vibration characteristic testing of an electronic device and adjustment of the resonant frequency.

FIG. 5 is a cross-sectional view showing the form of the cutting mark of a cutting pattern.

FIG. 6 is a diagram representing the first application form of an electronic device according to an embodiment of the invention.

FIG. 7 is a diagram representing the second application form of an electronic device according to an embodiment of the invention.

FIGS. 8A and 8B are diagrams representing an electronic device according to another embodiment of the invention.

FIG. 9 is a diagram representing a general electronic device that uses a package having an H-type cross-section.

FIGS. 10A and 10B are diagrams showing a general electronic device having a form in which a monitoring electrode terminal is disposed on one primary face side.

FIGS. 11A and 11B are diagrams showing a general electronic device having cutting patterns.

### DESCRIPTION OF EXEMPLARY EMBODIMENTS

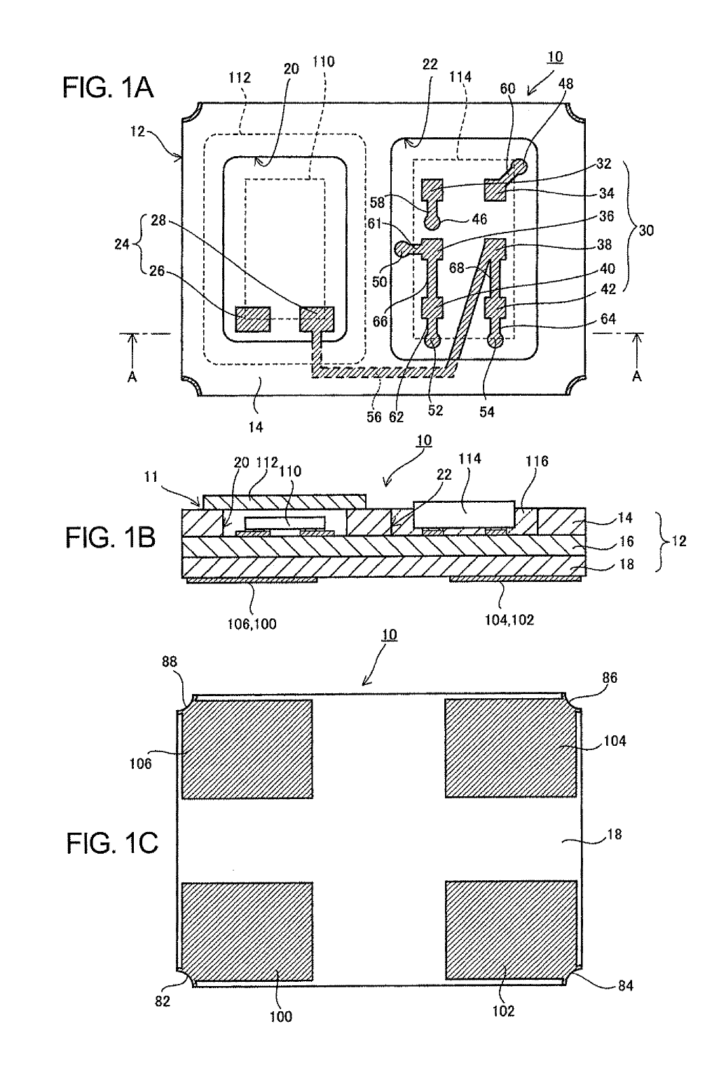

Hereinafter, an electronic device and a method of manufacturing an electronic device according to embodiments of the invention will be described in detail with reference to drawings. FIG. 1A is a diagram showing the planar structure of the electronic device, FIG. 1B is a diagram showing a cross section taken along line A-A shown in FIG. 1A, and FIG. 1C is a diagram showing a rear-face structure of the electronic device.

The electronic device 10 according to this embodiment is basically configured by a resonator element 110, an IC chip 114 as a semiconductor device, and a package 11.

As the resonator element 110, a quartz crystal resonator element such as an AT cut quartz crystal resonator element can be used. In addition, the resonator element 110 may be a tuning fork-type quartz crystal resonator element, a surface acoustic wave crystal resonator element, or the like, that has a different cut angle of a crystal element plate or form of main oscillation. As the material of the resonator element, lithium tantalate, lithium niobate, or the like other than crystal may be used. Furthermore, instead of the quartz crystal resonator element, various types of resonator elements other than a piezoelectric resonator element can be used. For example, even in a case where an MEMS (Micro Electro Mechanical Systems) resonator element that is formed by processing a silicon substrate or the like is used, the electronic device 10 according to this embodiment can be configured.

As the IC chip 114, an integrated circuit that is configured by a semiconductor device having a circuit structure for oscillating a resonator (a piezoelectric resonator in a case where a piezoelectric element plate is mounted as the resonator element 110) or the like may be used. In the IC chip 114, a plurality of electrode pads (not shown in the figure) is disposed.

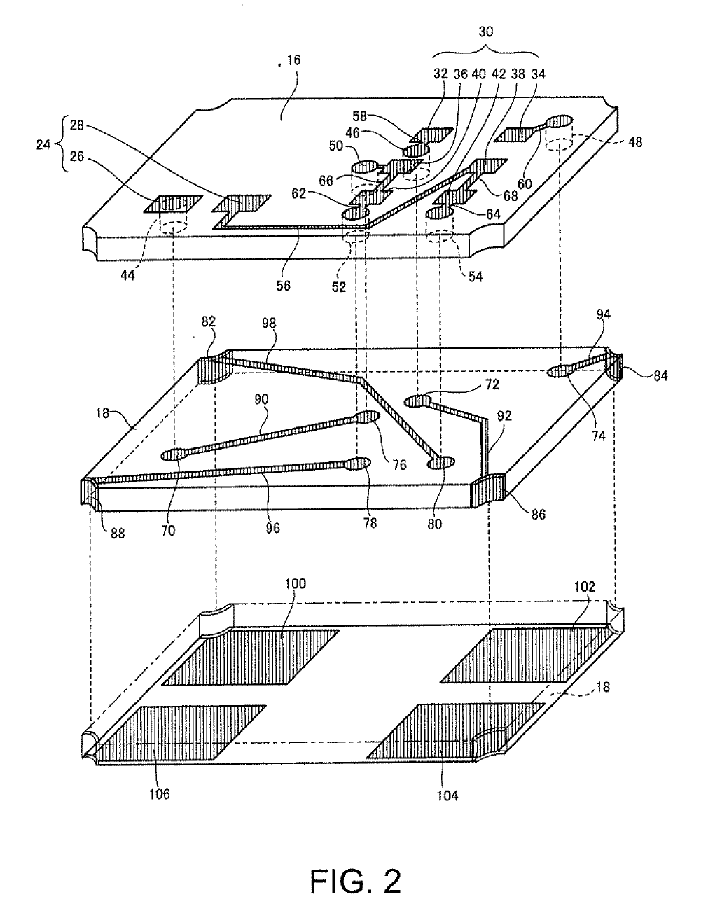

The package 11 is basically configured by a base substrate 12 and a lid body 112 that is used for configuring a resonator by sealing a resonator element 110 mounted on the base substrate 12. The base substrate 12 according to this embodiment is configured by stacking the first substrate 14, the second substrate 16, and the third substrate 18. The constituent materials of the substrates are formed from a ceramic materials such as an alumina ceramic, glass ceramic, or the like, and the substrates are integrated together by being stacked and sintered using a green sheet method. In the second substrate 16 and the third substrate 18, metal patterns are formed. Thus, in FIG. 2, an exploded perspective view of the second substrate 16 and the third substrate is shown so as to clearly show the configuration of the metal patterns formed on the second substrate 16 and the third substrate 18.

The first substrate 14 is the uppermost layer of the substrates configuring the base substrate 12 and is a frame body that forms the first concave portion 20 and the second concave portion 22 that surround the outer periphery of the resonator element 110 and the IC chip 114. The first concave portion 20 forms an internal space that houses the resonator element 110 therein. In addition, the second concave portion 22 forms a space that houses the IC chip 114 therein. The first substrate 14 is formed so as to have a thickness that is at least thicker than that of the resonator element 110. The reason for this is to enable the first concave portion 20 to be sealed by using the lid body 112, to be described in detail later, after housing the resonator element 110 in the first concave portion 20.

The second substrate 16 is a middle layer of the substrates configuring the base substrate 12 and, on the first primary face that is a face bonded to the above-described first substrate 14, has metal patterns and via holes that are used for laying down the metal patterns formed on the first primary face to the second primary face that is positioned on the side of the rear face of the first primary face. As the metal patterns formed on the first primary face, there are resonator element mounting pads 24 that are used for mounting the resonator elements 110, IC chip mounting pads 30 that are used for mounting the IC chips 114, and connection patterns 56, 58, 60, 61, 62, and 64 that electrically connect the metal patterns and the via holes. In the second substrate 16 according to this embodiment, there are the first resonator element mounting pad 26 and the second resonator element mounting pad 28 as the resonator element mounting pads 24. In addition, as the IC chip mounting pads 30, a GND pad 32, an fout pad 34, the first resonator element connecting pad 36 (the first semiconductor device connecting pad), the second resonator element connecting pad 38 (the first semiconductor device connecting pad), a Vc pad 40 (the second semiconductor device connecting pad), a Vdd pad 42 (the second semiconductor device connecting pad), and the like are included.

In addition, as the via holes, the first via hole 44 to the sixth via holes 54 are included. From among the via holes, the first via hole 44 is disposed right below the first resonator element mounting pad 26. In addition, the second via hole 46 is disposed between the GND pad 32 and the first resonator element connecting pad and is connected to the GND pad 32 through the connection pattern 58. The third via hole 48 is disposed between the Lout pad 34 and a corner potion close to the fout pad 34 and is connected to the fout pad 34 through the connection pattern 60. The fourth via hole 50 is disposed in a tip end position of the connection pattern that is disposed so as to extend from the first resonator element connecting pad 36 to the side of the resonator element mounting position. In addition, the fifth via hole 52 is disposed at a position that is in the point symmetry with the first resonator element connecting pad 36 with respect to the Vc pad 40 as the base point and is connected to the Vc pad 40 through the connection pattern 62. Furthermore, the sixth via hole is disposed at a position that is in the point symmetry with the second resonator element connecting pad 38 with respect to the Vdd pad 42 as the base point and is connected to the Vdd pad 42 through the connection pattern 64.

The second substrate 16 that configures the package of the electronic device 10 according to this embodiment has cutting patterns 66 and 68 that electrically connect the first resonator element connecting pad 36 and the Vc pad 40 and the second resonator element connecting pad 38 and the Vdd pad 42, respectively.

The third substrate 18 is a lowermost layer of the substrates configuring the base substrate 12 and has the first primary face bonded to the second substrate 16 and the second primary face that is exposed to the outside of the package. On the four corners of the third substrate 18, notches are formed, and the first to fourth castellations 82 to 88 are formed. On the first primary face of the third substrate 18, via hole correspondence pads and connection patterns corresponding to lay-down positions of the via holes of the second substrate 16 are formed. As the via hole correspondence pads, there are the first via hole correspondence pad 70 to the sixth via hole correspondence pad 80, which are formed so as to be disposed at positions corresponding to the first via hole 44 to the sixth via hole 54.

The first via hole correspondence pad 70 and the fourth via hole correspondence pad 76 are connected to each other through a connection pattern 90. Accordingly, the first resonator element mounting pad 26 and the first resonator element connecting pad 36 are electrically connected to each other. In addition, the second via hole correspondence pad 72 is connected to the third castellation 86 through a connection pattern 92. The third via hole correspondence pad 74 is connected to the second castellation 84 through a connection pattern 94. The fifth via hole correspondence pad 78 is connected to the fourth castellation 88 through a connection pattern 96. In addition, the sixth via hole correspondence pad is connected to the first castellation 82 through a connection pattern 98.

On the second primary face of the third substrate 18, four external mounting terminals are formed. Each of the four external mounting terminals is connected to one of the first to fourth castellations 82 to 88 formed on the four corners of the third substrate 18. The four external mounting terminals configure a GND terminal 104, an fout terminal 102, a Vc terminal 106, and a Vdd terminal 100 in accordance with the attributes of pads (the GND pad 32, the fout pad 34, the Vc pad 40, and the Vdd pad 42) that are electrically connected thereto through the castellations and the connection electrodes.

The lid body 112 is a member that covers an upper opening portion of the first concave portion 20 of the first substrate 14. The lid body 112 may be formed to have a flat plate shape or a cap shape taken along the outer periphery of the first concave portion 20, that is, a shape that covers the first concave portion 20 in a convex shape. In this embodiment, as an example of the lid body 112, a plate-shaped metal lid is used. In addition, for joining the lid body 112 and the first substrate 14, a metal brazing material such as a seam ring, a brazing material such as low melting point glass, or the like, which is not shown in the figure, may be used.

In the package 11, which has the above-described configuration, according to this embodiment, in a state in which the cutting patterns 66 and 68 are not cut off, the Vc terminal 106 and the first resonator element mounting pad 26 are electrically connected, and the Vdd terminal 100 and the second resonator element mounting pad 28 are electrically connected. Accordingly, the Vc terminal 106 and the Vdd terminal 100 serve as monitoring electrode terminals. On the other hand, after the cutting patterns 66 and 68 are cut off, the first resonator element connecting pad 36 and the Vc pad 40 are electrically separated from each other, and the second resonator element connecting pad 38 and the Vdd pad 42 are electrically separated from each other. Accordingly, the Vc terminal 106 and the Vdd terminal 100 respectively become terminals responsible for unique functions. Therefore, the vibration characteristics of the resonator element 110 cannot be directly detected from the outside (the side of the external mounting terminal forming face) of the package 11.

The resonator element 110 is mounted in the first resonator element mounting pad 26 and the second resonator element mounting pad 28 through a conductive bonding agent or the like. Accordingly, the first resonator element connecting pad 36 and the second resonator element connecting pad 38 are electrically connected to excitation electrodes, not shown in the figure, of the resonator element 110. Here, in a case where a surface acoustic wave crystal resonator element or the like is used as the resonator element 110, a technique such as wire bonding may be used instead of mounting through the conductive bonding agent.

The IC chip 114 is mounted in the IC chip mounting pads 30 (the GND pad 32, the fout pad 34, the first resonator element connecting pad 36, the second resonator element connecting pad 38, the Vc pad 40, and the Vdd pad 42) disposed in the second concave portion 22 through a metal bump or the like using flip-chip bonding. Accordingly, the first resonator element connecting pad 36, the second resonator element connecting pad 38, the fout pad 34, and the Vdd pad 42 are connected through the IC chip 114, and thus the resonator element 110 oscillates based on the operation conditions recorded in the IC chip 114.

In the outer periphery of the IC chip 114, in the internal area of the second concave portion 22 in which the IC chip 114 is mounted, a resin member 116 is filled up. By filling up with the resin member 116, deterioration of the vibration characteristics due to the attachment of moisture to the IC chip 114 mounting face or formation of a short circuit due to the attachment of dust, and the like can be prevented. Accordingly, the resin member 116 having an insulating property is used. As an example, a general mold resin can be used.

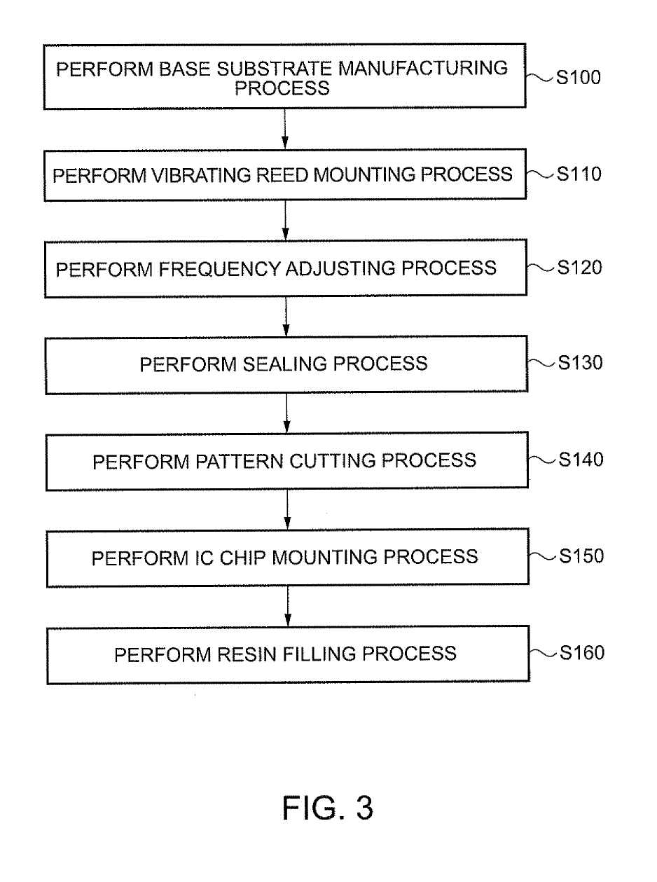

Next, a method of manufacturing the electronic device having the above-described configuration will be described with reference to FIG. 3.

First, from among the first substrate 14, the second substrate 16, and the third substrate 18 of the bases substrate 12 that are formed in the shapes of each substrate, metal patterns are formed on the second substrate 16 and the third substrate 18. The formation of the metal patterns is performed by using a technique such as screen printing, the metal pattern uses a base layer formed from tungsten, molybdenum, or the like, and the second and third substrates 16 and 18 are integrated as one body by being sintered with the first substrate 14 (base substrate manufacturing process: S100). Then, after the sintering process, a plating process is performed for the metal patterns so as to form a nickel layer and a gold layer.

The first resonator element mounting pad 26 and the second resonator element mounting pad 28 disposed in the first concave portion 20 of the formed base substrate 12 are coated with a conductive bonding agent. A resonator element 110 is mounted on the first resonator element mounting pad 26 and the second resonator element mounting pad 28 that are coated with the conductive bonding agent, thereby mounting of the resonator element 110 is performed (resonator element mounting process: S110).

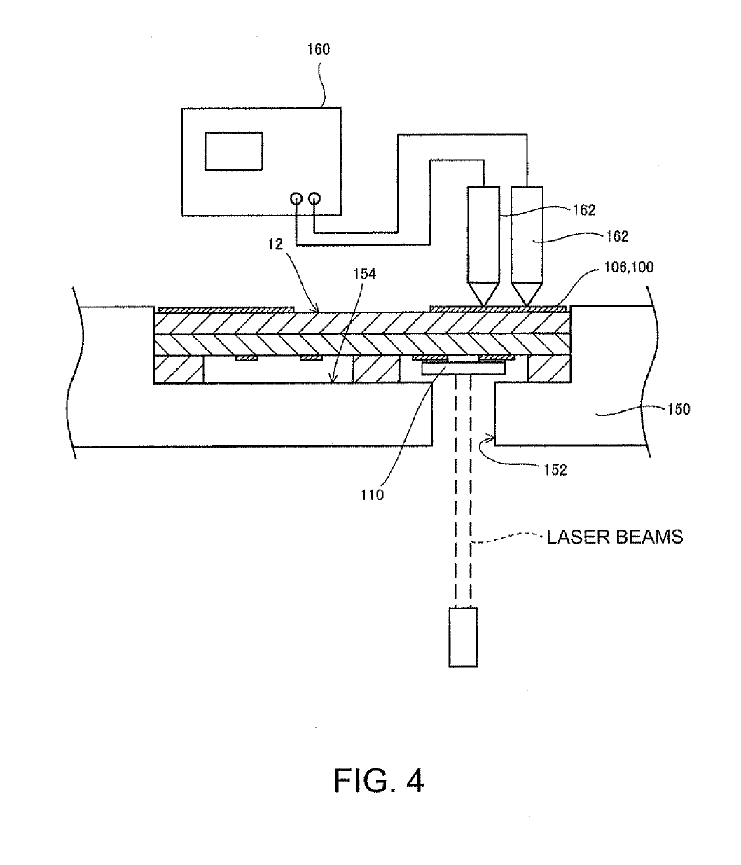

Then, the base substrate 12 on which the resonator element 110 is mounted is set in a holder 150 as shown in FIG. 4. In the holder 150, a concave portion 154 having an opening portion 152 on its bottom face is formed, and the base substrate 12 is set in the holder 150 such that the excitation electrodes (not shown in the figure) of the resonator element 110 can be peeped through the opening portion 152. A probe 162 of a characteristic test device 160 such as a network analyzer is brought into contact with the Vc terminal 106 and the Vdd terminal 100 of the base substrate 12 set as above. Here, as the characteristic test device 160, a device that can measure equivalent parameters such as the resonant frequency, a CI (crystal impedance) value, inductance, or capacitance of the resonator element 110 mounted on the base substrate 12 may be used.

Then, the characteristics of the resonator element 110 such as the resonant frequency and the like are detected by bringing the probe 162 of the characteristic test device 160 into contact with the Vc terminal 106 and the Vdd terminal 100, and the resonant frequency is adjusted by emitting laser beams to the excitation electrode of the resonator element 110 through the opening portion 152 of the holder 150 (frequency adjusting process: S120).

After the frequency adjusting process is completed, the upper opening portion of the first concave portion 20 is sealed with the lid body 112. For the bonding of the lid body 112, seam welding using a seam ring not shown in the figure, a liquid phase diffusion bonding method using a metal-based brazing material, or the like can be used. By sealing the first concave portion 20 with the lid body 112, a resonator is configured. By sealing the first concave portion 20 before a pattern cutting process to be described in detail later, deterioration of the vibration characteristics due to the attachment of dust to the resonator element 110 generated by cutting the cutting patterns 66 and 68 can be prevented (sealing process: S130).

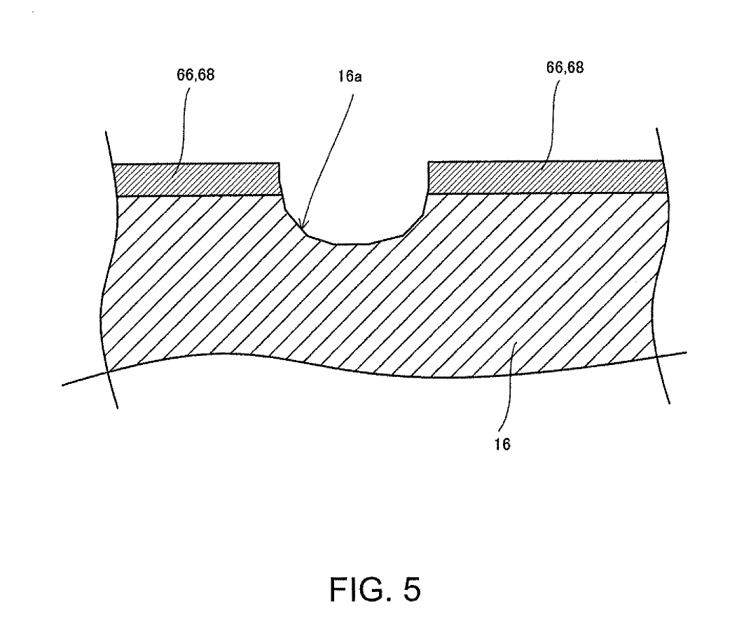

After completion of the frequency adjusting process, the base substrate 12 on which the resonator element 110 is mounted is detached from the holder 150, and the cutting patterns 66 and 68 are cut. The cutting of the cutting patterns 66 and 68 can be performed by emitting laser beams such as Nd—YAG laser beams or Nd—YVO₄ laser beams. The cutting mark 16a of the cutting patterns 66 and 68 cut off by the laser beams, as shown in FIG. 5, is in a state in which one primary face, that is, the front face of the second substrate 16 of the base substrate 12 is concavely dented.

The emitting of the laser beams may be performed once or a plurality of times. In a case where the laser beams are emitted a plurality of times, the width of the cut portion can be increased by displacing the emitting position along the wiring direction of the cutting patterns 66 and 68. In addition, in a case where the laser beams are emitted a plurality of times, it is preferable that the laser beams are emitted while dust generated by the emission of the laser beams is suctioned and eliminated. The reason for this is that there is a possibility that the cutting patterns 66 and 68 will be hindered from being electrically cut off due to the attachment of dust which includes metal patterns generated by emission of the laser beams performed a plurality of times to a place where the cutting mark 16a cut off by the laser beams remains (pattern cutting process: S140).

After the pattern cutting process, an IC chip 114 is mounted in the second concave portion 22. The IC chip 114 is mounted by flip-chip bonding through a gold bump or the like (IC chip mounting process: S150). After the IC chip 114 is mounted, a resin member 116 is filled in a gap portion of the second concave portion 22 and is solidified (resin filling process: S160).

According to the electronic device 10 formed as above, a configuration in which the resonator element 110 and the IC chip 114 are disposed in the horizontal direction that can be regarded as being appropriate for reducing the height thereof is formed. In addition, in testing or adjusting the vibration characteristics of the resonator element 110, by using the external mounting terminal as a monitoring electrode terminal, the area with which the probe 162 is brought into contact can be reliably secured even in a case where the electronic device is miniaturized. Furthermore, since the external mounting terminal is used as the monitoring electrode terminal, the probe 162 can be brought into contact with the monitoring electrode terminal from the rear face side in a state in which the base substrate 12, on which the resonator element 110 is mounted, is set in the holder 150. Accordingly, the resonant frequency can be adjusted while detecting the vibration characteristics and the like.

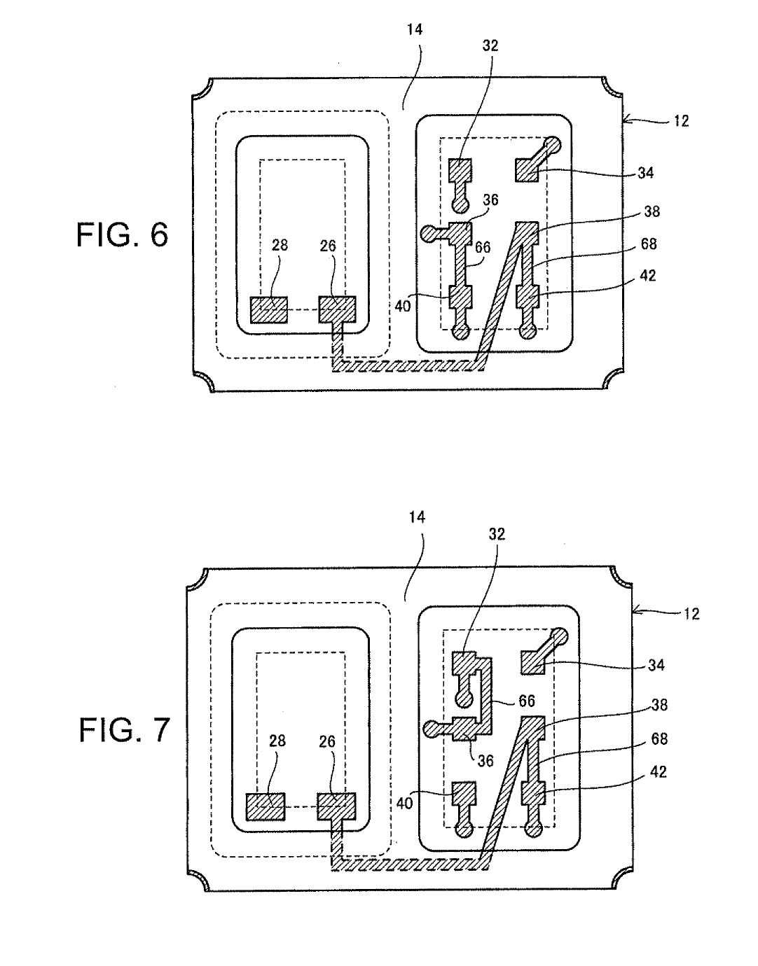

In the above-described embodiment, the pattern widths of the cutting patterns 66 and 68 are represented to be the same as the pattern widths of the other metal patterns in the figure. However, as shown in FIG. 6, the pattern widths of the cutting patterns 66 and 68 may be formed to be less than those of the other metal patterns. By using such a configuration, the cutting patterns 66 and 68 can be easily cut off, whereby the reliability of the cutting process can be improved.

In addition, in the electronic device according to the above-described embodiment, as shown in FIG. 7, the cutting pattern 66 (or the cutting pattern 68) may be configured to be connected to the GND pad 32. By using such a configuration, the GND pad 32 serves as the second semiconductor device connecting pad, and, in the frequency adjusting process, the GND terminal 104 and the Vdd terminal 100 serve as monitoring electrode terminals. As above, in the package 11 according to this embodiment, by configuring the external mounting terminal to be used as the monitoring electrode terminal, the combination of connection places of the cutting patterns 66 and 68 can be changed, whereby restrictions on the design of the metal patterns can be alleviated.

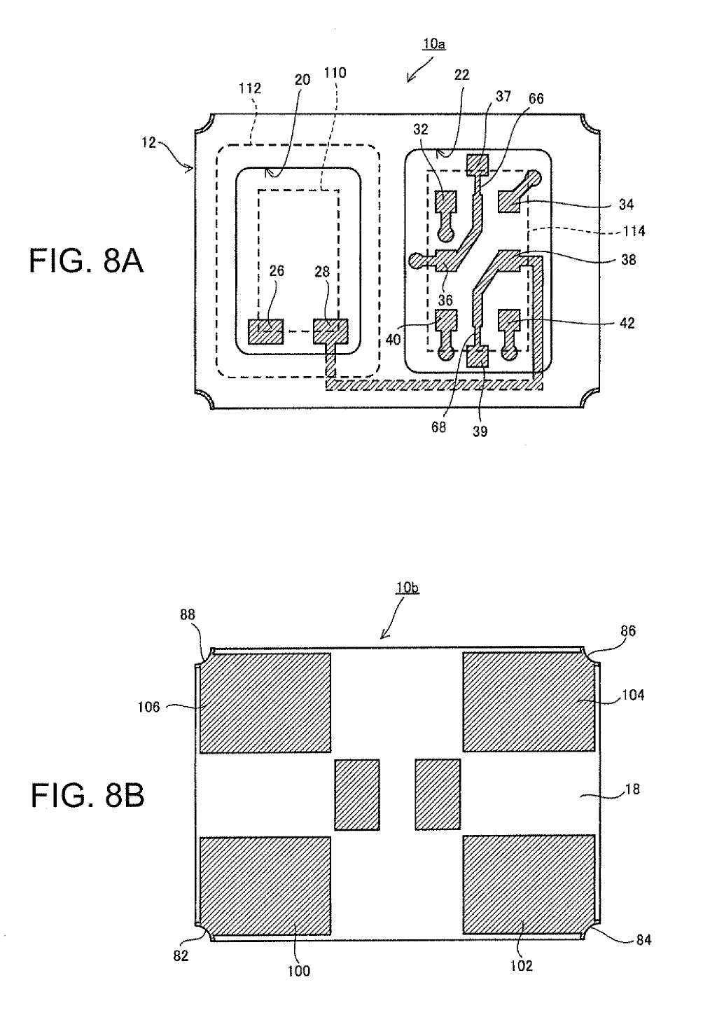

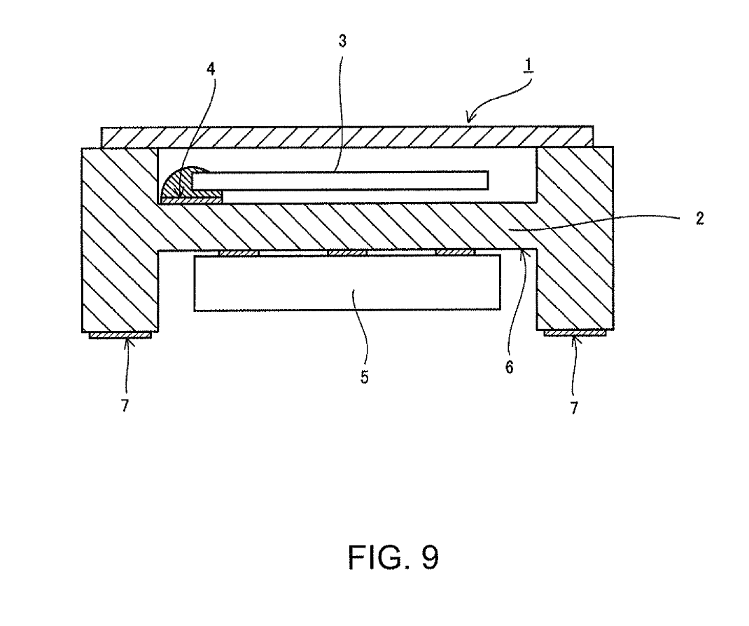

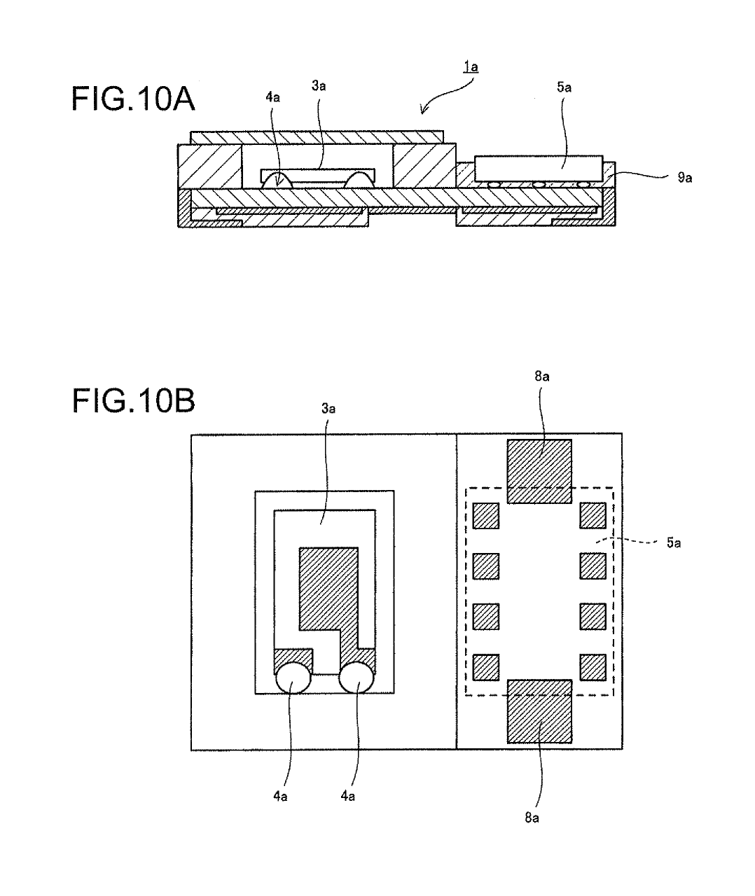

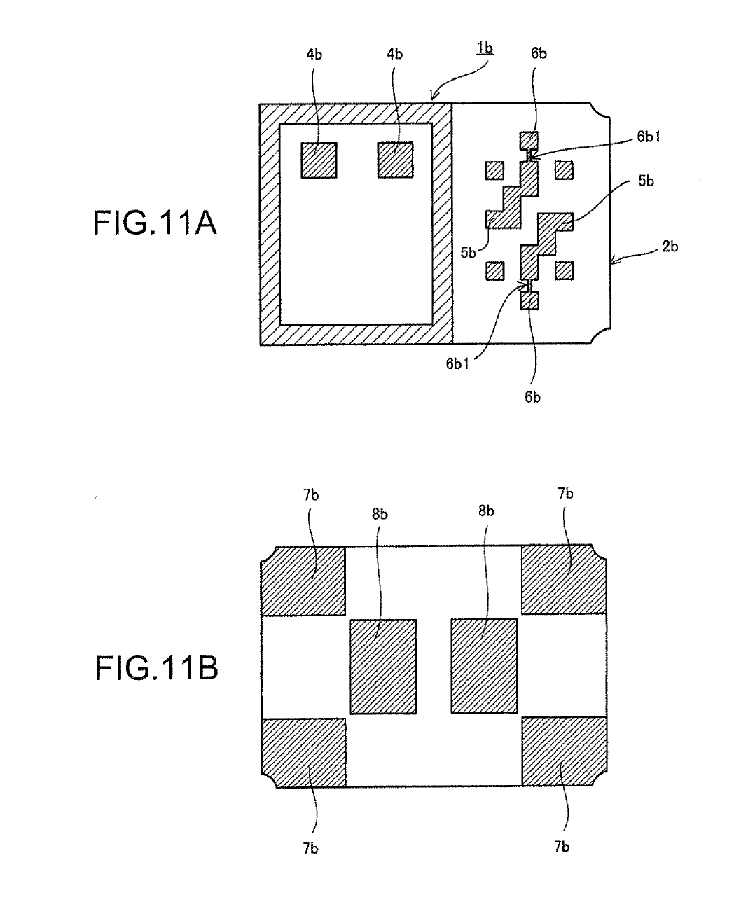

In addition, in the electronic device according to the above-described embodiment, the external mounting terminal is configured to serve as a monitoring electrode terminal. However, even an electronic device having a form as shown in FIGS. 8A and 8B in which an external mounting terminal and a monitoring electrode terminal are separately arranged can be regarded as belonging to the scope of an embodiment of the invention. In addition, regarding FIGS. 8A and 8B, FIG. 8A is a diagram showing a planar configuration of an electronic device, and FIG. 8B is a diagram showing the rear-side configuration of the electronic device.

The basic configuration of the electronic device 10a shown in FIGS. 8A and 8B is the same as that of the electronic device 10 according to the above-described embodiment. A difference between the electronic devices is that intermediate diameter pads 37 and 39, which are not electrically connected to the IC chip 114, are disposed in the configuration of the base substrate of the electronic device 10a. The intermediate diameter pads 37 and 39 are electrically connected to monitoring electrode terminals that are formed on the second primary face of the third substrate 18.

In addition, a cutting pattern 66 is disposed between the first resonator element connecting pad 36 and the intermediate diameter pad 37, and a cutting pattern is disposed between the second resonator element connecting pad 38 and the intermediate diameter pad 39. In the electronic device 10a including a base substrate 12 having the above-described configuration, the cutting patterns 66 and 68 are cut off so as to form a concave dent portion that concavely dents the surface of the base substrate 12 after completion of the above-described frequency adjusting process, and the IC chip 114 is mounted thereon. Even in the electronic device having the above-described configuration, by forming cutting marks that become a concave dent shape at a time of cutting off the cutting patterns 66 and 68, the cutting off of the cutting patterns 66 and 68 can be reliably performed.

In addition, for easy understanding of the description, the electronic device 10 shown in FIGS. 1A to 1C, 6, and 7 and the electronic device 10a shown in FIGS. 8A and 8B represent a state in which the cutting patterns 66 and 68 are not cut off. However, in electronic devices 10 and 10a that are actually configured, the cutting patterns 66 and 68 are in the cut-off state.

The entire disclosure of Japanese Patent Application No. 2010-063876, filed Mar. 19, 2010 is expressly incorporated by reference herein.

What is claimed is:

1. An electronic device having a base substrate on which a resonator element and a semiconductor device are mounted by being disposed in a horizontal direction, the electronic device comprising on one primary face of the base substrate:
a resonator element mounting pad that is used for mounting the resonator element;
a first semiconductor device connecting pad that is electrically connected to the resonator element mounting pad;
a relay pad that is electrically connected to a monitoring electrode terminal formed on the other primary face of the base substrate; and
a cutting pattern that electrically connects the first semiconductor device connecting pad and the relay pad,
wherein the cutting pattern is cut off in a state in which the semiconductor device is mounted, and
a concave dent portion is included on the surface of the base substrate that is a cutting-off position of the cutting pattern.

2. The electronic device according to claim 1,
wherein the relay pad is a second semiconductor device connecting pad that is used for mounting the semiconductor device, and
the monitoring electrode terminal is a mounting terminal that is formed on the other face of the base substrate.

3. A method of manufacturing an electronic device that has a base substrate having one face on which a resonator element mounting pad that is used for mounting a resonator element, a first semiconductor device connecting pad that is electrically connected to the resonator element mounting pad, a relay pad that is electrically connected to a monitoring electrode terminal formed on the other face, and a cutting pattern that electrically connects the first semiconductor device connecting pad and the relay pad and capable of mounting the resonator element and the semiconductor device by being disposed in a horizontal direction, the method comprising:
mounting the resonator element on the resonator element mounting pad;
performing adjustment of oscillation of the resonator element and a resonant frequency through the monitoring electrode terminal; and
forming a concave dent portion on the surface of the base substrate by cutting off the cutting pattern after the performing of adjustment.
